(19) United States
(12) Patent Application Publication
(10) Pub. No.: US 2013/0221198 A1
(43) Pub. Date: Aug. 29, 2013

(54) RADIATION DETECTION APPARATUS

(71) Applicant: CANON KABUSHIKI KAISHA, (US)

(72) Inventors: Satoru Sawada, Fujioka-shi (JP); Masato Inoue, Kumagaya-shi (JP); Shinichi Takeda, Honjo-shi (JP); Takamasa Ishii, Honjo-shi (JP); Taiki Takei, Okegawa-shi (JP); Kota Nishibe, Honjo-shi (JP)

(73) Assignee: CANON KABUSHIKI KAISHA, Tokyo (JP)

(21) Appl. No.: 13/762,464

(22) Filed: Feb. 8, 2013

(30) Foreign Application Priority Data
Feb. 23, 2012 (JP) 2012-037803

(51) Int. Cl. H01L 27/146

(52) U.S. Cl. CPC H01L 27/14601
USPC 250/208.1

(57) ABSTRACT

A radiation detection apparatus include a sensor substrate having a pixel array and a connection terminal connected to the pixel array on a first surface; and a scintillator layer that is arranged on the first surface side; a circuit board that is arranged on a side of the scintillator layer that is opposite to a side facing the sensor substrate; and a connection portion configured to connect the connection terminal to the circuit board. The scintillator layer is arranged so as to cover the pixel array but expose the connection terminal. The circuit board and the connection portion are arranged in locations where they do not protrude from the outer edge of the first surface of the sensor substrate.

### BACKGROUND OF THE INVENTION

1. Field of the Invention

The present invention relates to a radiation detection apparatus.

2. Description of the Related Art

Japanese Patent Laid-Open No. 9-152486 discloses a radiation detection apparatus, in which photoelectric conversion elements are arranged on the front side surface of a sensor substrate, and processing circuits for processing signals obtained by the photoelectric conversion elements are arranged on the back side of the sensor substrate. Flexible wirings for connecting the photoelectric conversion elements to the processing circuits are arranged so as to extend beyond the outer edge of the sensor substrate. Japanese Patent Laid-Open No. 2002-101345 proposes, in order to minimize a radiation detection apparatus, a configuration in which no flexible wiring is arranged outside the outer edge of a sensor substrate. Specifically, the sensor substrate is provided with a through hole, through which a photoelectric conversion element arranged on the front side of the sensor substrate and a processing circuit arranged on the back side of the sensor substrate are connected to each other. Japanese Patent Laid-Open No. 2010-262134 proposes a radiation detection apparatus of a back-side illumination type, in which radiation that entered the back side of a sensor substrate is converted in a scintillator layer that is arranged on the front side of the sensor substrate.

### SUMMARY OF THE INVENTION

A sensor substrate that is provided with a through hole, as with that of the radiation detection apparatus proposed in Japanese Patent Laid-Open No. 2002-101345, has a reduced strength. Further, an additional process for forming the through hole is required, thereby increasing the cost and time needed for the production of the radiation detection apparatus. In the radiation detection apparatus of Japanese Patent Laid-Open No. 2010-262134, the scintillator layer covers the entire sensor substrate, and a flexible wiring is arranged so as to extend beyond the outer edge of the sensor substrate, as with that of Japanese Patent Laid-Open No. 9-152486, so that the radiation detection apparatus is not sufficiently minimized. One aspect of the present invention provides a technique for minimizing a radiation detection apparatus while maintaining the strength of a sensor substrate.

An aspect of the present invention provides a radiation detection apparatus comprising: a sensor substrate having a first surface and a second surface opposite to the first surface, wherein a pixel array and a connection terminal connected to the pixel array are arranged on the first surface; a scintillator layer that is arranged on the first surface side of the sensor substrate and converts radiation that entered the second surface side of the sensor substrate into light of a wavelength detectable by the pixel array; a circuit board that is arranged on a side of the scintillator layer that is opposite to a side facing the sensor substrate, and includes a circuit for controlling an operation of the pixel array; and a connection portion configured to connect the connection terminal to the circuit board, wherein the scintillator layer is arranged so as to cover the pixel array but expose the connection terminal, the circuit board and the connection portion are arranged in locations where they do not protrude from the outer edge of the first surface of the sensor substrate.

Further features of the present invention will become apparent from the following description of exemplary embodiments (with reference to the attached drawings).

### BRIEF DESCRIPTION OF THE DRAWINGS

The accompanying drawings, which are incorporated in and constitute a part of the specification, illustrate embodiments of the invention, and together with the description, serve to explain the principles of the invention.

FIGS. 1A and 1B are diagrams illustrating an example of a configuration of a sensor unit according to a first embodiment of the present invention.

FIGS. 2A and 2B are diagrams illustrating an example of a configuration of a radiation detection apparatus according to a second embodiment of the present invention.

FIGS. 3A and 3B are diagrams illustrating an example of a configuration of a radiation detection apparatus according to a third embodiment of the present invention.

### DESCRIPTION OF THE EMBODIMENTS

The following describes embodiments of the present invention with reference to the accompanied drawings. Throughout the various embodiments, the same reference numerals are given to the similar components and any duplicated descriptions thereof are omitted. Also, the embodiments can arbitrarily be modified and combined with each other.

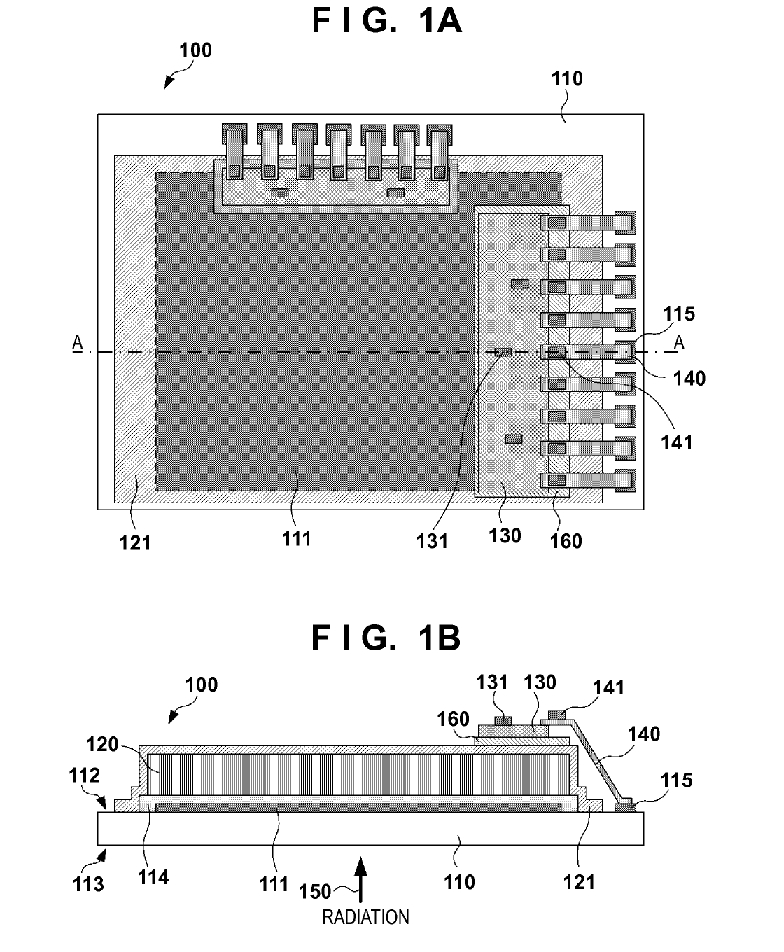

An example of a structure of a sensor unit 100 according to a first embodiment of the present invention will now be described with reference to FIGS. 1A and 1B. The sensor unit 100 may be used as part of a radiation detection apparatus, as described later. FIG. 1A is a plan view of the sensor unit 100, and FIG. 1B is a cross-sectional view taken along the line A-A in FIG. 1A. The sensor unit 100 can mainly include a sensor substrate 110, a scintillator layer 120, a circuit board 130, and a connection portion 140. Although FIG. 1A shows a pixel array 111 for illustrative purposes, the pixel array 111 cannot actually be viewed since it is disposed under a scintillator protection layer 121.

The pixel array 111 is formed on one surface (a first surface) of the sensor substrate 110. In the following description, the surface on which the pixel array 111 is formed is referred to as a light-receiving surface 112, and an opposite surface (a second surface) is referred to as a radiation-entrance surface 113. In the pixel array 111, photoelectric conversion elements are arranged in an array, each photoelectric conversion element being configured to detect light and convert the detected light into an electric signal. The pixel array 111 is covered with a sensor protection layer 114. A connection terminal 115, which is made from metal such as Al and provided on the sensor substrate 110, is connected to the pixel array 111 via a conductive line (not shown).

The scintillator layer 120 is arranged on the light-receiving surface 112 side (a first surface side) of the sensor substrate 110 and covers the entire pixel array 111 but exposes the connection terminal 115. The scintillator layer 120 converts radiation 150 that entered the sensor unit 100 into light of a wavelength detectable by the pixel array 111. The sensor unit 100 according to the present embodiment is of a back-side illumination type and detects the radiation 150 that entered the radiation-entrance surface 113 side (a second surface side) of the sensor substrate 110. The radiation 150 that entered the radiation-entrance surface 113 side is most likely converted into light on the side of the scintillator layer 120 that is close to the pixel array 111. That is, the vicinity of the pixel array 111 is most luminous. Therefore, the amount of scattered light is reduced and resolution is improved, compared with the case where radiation entered the opposite side thereto. The scintillator layer 120 may be covered with the scintillator protection layer 121. By covering the scintillator layer 120 with the scintillator protection layer 121, it is possible to protect the scintillator layer 120 against any influx of fluid from the outside air and structural damage due to impact from the outside.

Circuits, such as ICs 131 and resistors (not shown), are formed on the circuit board 130. An operation of the pixel array 111 is controlled using these circuits. Examples of such control can include control of scanning and timing of the pixel array 111, and processing of signals obtained by the pixel array 111. The circuit board 130 is arranged on the side of the scintillator layer 120 that is opposite to the side facing the sensor substrate 110. The circuit board 130 and the connection terminal 115 are electrically connected to each other via the connection portion 140. In the sensor unit 100 of a back-side illumination type, the connection terminal 115, the circuit board 130, and the connection portion 140 are arranged on the same side (the light-receiving surface 112 side) of the sensor substrate 110. This is because, if the circuit board 130 and the connection portion 140 are arranged between the radiation-entrance surface 113 side (the second surface side) of the sensor substrate 110 and the scintillator layer 120, the entered radiation 150 might be absorbed by the circuit board 130 and the connection portion 140. Accordingly, it is possible to arrange the circuit board 130 and the connection portion 140 in locations where they do not protrude from the outer edge of the light-receiving surface 112 (the outer edge of the first surface) of the sensor substrate 110, in other words, it is possible to arrange them within the outer edge. It is also possible, for example, to adjust the length of the connection portion 140 (the distance between a portion that is connected to the connection terminal 115 and a portion that is connected to the circuit board 130) so that the connection portion 140 does not bend so as to protrude from the outer edge of the light-receiving surface 112. If the connection portion 140 has a high flexibility and is easily deformed, then part (for example, a central part) of the connection portion 140 that is connected to neither the connection terminal 115 nor the circuit board 130 can be fixed to a component on the sensor substrate 110 (for example, the scintillator protection layer 121) with an adhesive material or the like.

The sensor unit 100 may further include an electromagnetic shield layer 160. The electromagnetic shield layer 160, which may be arranged between the circuit board 130 and the scintillator layer 120, shields electromagnetic waves generated by circuits included in the circuit board 130 and reduces an influence on the operation of the pixel array 111. The electromagnetic shield layer 160 of the present embodiment is larger than the circuit board 130 but smaller than the pixel array 111. It is thus possible not only to reduce the influence on the operation of the pixel array 111 but also to achieve weight reduction of the sensor unit 100. According to the present embodiment, the electromagnetic shield layer 160 also exists between circuits, such as IC 141 included in the connection portion 140, and the scintillator layer 120, so as to shield electromagnetic waves generated by the circuits of the connection portion 140. Since the sensor unit 100 is of a back-side illumination type, the electromagnetic shield layer 160 does not prevent the detection of the radiation 150 that entered the radiation-entrance surface 113 side.

Examples of specific configurations of the components of the sensor unit 100 will now be described. The sensor substrate 110 can be made from, for example, glass, a heat resistant plastic, or the like. If the sensor substrate 110 is made from glass, a thin glass substrate may be used in order to reduce radiation absorption by the glass. It is further possible to reduce the thickness of the sensor substrate 110 by dipping a glass substrate, on which the pixel array 111 was formed and protected with a protection film, into hydrofluoric acid solution for chemical polishing. If the thickness of the sensor substrate 110 is reduced, then further minimization and weight reduction of the sensor unit 100 will be achieved. The sensor substrate 110 made from glass may have a thickness in a range between 30 μm and 500 μm, and specifically between 100 μm and 300 μm, in order to achieve an improvement in workability and handling ability. Since, in the sensor unit 100 of the present embodiment, the connection terminal 115 and the circuit board 130 are arranged on the same side (the light-receiving surface 112 side), no through hole for connecting them is required to be formed in the sensor substrate 110. This thus can prevent a reduction in the strength of the sensor substrate 110 due to the formation of the through hole, and improves yield.

The pixel array 111 is a region where pixels are arranged in a matrix, each pixel having a conversion element, such as a MIS type sensor and a PIN type sensor that employ a semiconductor such as amorphous silicon (a-Si). A detailed description of the pixel array 111 is omitted because the pixel array 111 according to the present embodiment can be implemented by an existing configuration, such as a configuration in which pixels are arranged in a matrix on an insulating substrate, and a configuration in which pixels are arranged in a matrix on a single crystal semiconductor substrate. The sensor protection layer 114 may be made from, for example, a silicone resin, a polyimide resin, a polyamide resin, an epoxy resin, or a resin that includes an organic material such as paraxylene and acrylic, and specifically a thermosetting polyimide resin. Alternatively, the sensor protection layer 114 may be made from a heat-resistant resin, so that the sensor protection layer 114 does not deteriorate during processing, such as vapor deposition and annealing of the scintillator layer 120, which is associated with a high temperature condition.

The scintillator layer 120 can be a scintillator layer that is made from, for example, a particulate fluorescent material, such as Gd₂O₂S:Tb, or alkali halide. The scintillator layer 120 may have a column crystal structure that is obtained by vapor-depositing alkali halide, such as CsI:Na and CsI:Tl, on the sensor protection layer 114 with respect to the sensor substrate 110.

The scintillator protection layer 121 can be made from, for example, a hot-melt resin, such as a polyimide resin, an epoxy resin, a polyolefin resin, a polyester resin, a polyurethane resin, and a polyamide resin. Of these materials, a material that has low moisture permeability may specifically be used. Further, the scintillator protection layer 121 may have a thickness between approximately 10 μm and 200 μm. Between the scintillator protection layer 121 and the scintillator layer 120, a reflecting layer (not shown) may further be arranged that is made from, for example, metal having a high reflectance, such as Al, Ag, Cr, Cu, Ni, Ti, Mg, Rh, Pt, and Au or alloy thereof. With this measure, an improvement in luminance characteristics of the sensor unit 100 is achieved.

The electromagnetic shield layer 160 can be made from metal in the form of a foil, a sheet, or a plate, such as Ag, Cu, Au, Al, and Ni, a conductive coating material into which such metal is incorporated, a conducting polymer in which stainless fibers are dispersed, or the like. Of these materials, Al that is superior in workability, material cost, and the like, may be specifically used. If foil-like metal is selected, the foil-like metal may be bonded to a film-like resin material, so as to make stabilization of the foil form and an improvement in workability possible. This film-like resin material may be a film material, such as polyethylene terephthalate, polycarbonate, vinyl chloride, polyethylene naphthalate, polyimide, and acrylic. Further, the electromagnetic shield layer 160 may be fixed to the scintillator protection layer 121 with an adhesive material (not shown). This adhesive material may be, for example, a rubber adhesive material, an acrylic adhesive material, a styrene-conjugate diene block copolymer adhesive material, or a silicone adhesive material. A thin electromagnetic shield layer 160 has a reduced electromagnetic shield effect, whereas a thick electromagnetic shield layer 160 increases the weight of the sensor unit 100. Therefore, taking into consideration the tradeoff between the thin electromagnetic shield layer 160 and the thick electromagnetic shield layer 160, the thickness of the electromagnetic shield layer 160 may be in a range from 5 μm to 3 mm, and in particular from 10 μm to 1 mm.

The circuit board 130 is a substrate, which is made from glass epoxy, paper phenol, paper epoxy, or the like, and on which a circuit (pattern) wiring that is made from a conductive material, such as a copper foil, is formed and members that constitute circuits are mounted. A contact hole may be formed in part of the circuit board 130, and the circuit board 130 and the electromagnetic shield layer 160 may be bonded to each other with a conductive adhesive material, so that the electromagnetic shield layer 160 is grounded via the circuit board 130. Alternatively, the circuit board 130 is fixed to the electromagnetic shield layer 160 with an adhesive material or the like. Fixing the circuit board 130 to the electromagnetic shield layer 160 brings about an improvement in reliability of the connection of the circuit board 130 to the connection portion 140 against impact due to vibration or the like.

The connection portion 140 may be a flexible wiring substrate (FPC: Flexible Printed Circuit) in which a conductive pattern made of a copper foil is formed on a base material made from a film, such as a polyimide film and a polyester film, and covered with an insulating film for surface protection. The connection portion 140 is bonded to the connection terminal 115 with a conductive adhesive material. The connection portion 140 is also bonded to the circuit board 130 with a conductive adhesive material. The conductive adhesive material can be an adhesive material in which conductive filler, such as silver and gold, and a resin binder, such as acrylic and epoxy, are mixed.

As has been described above, according to the present embodiment, the circuit board 130 and the connection portion 140 are not located so as to extend over the outer edge of the sensor substrate 110, so that it is possible to minimize the sensor unit 100. Further, since the formation of a through hole in the sensor substrate 110 is not required, the strength of the sensor substrate 110 is maintained.

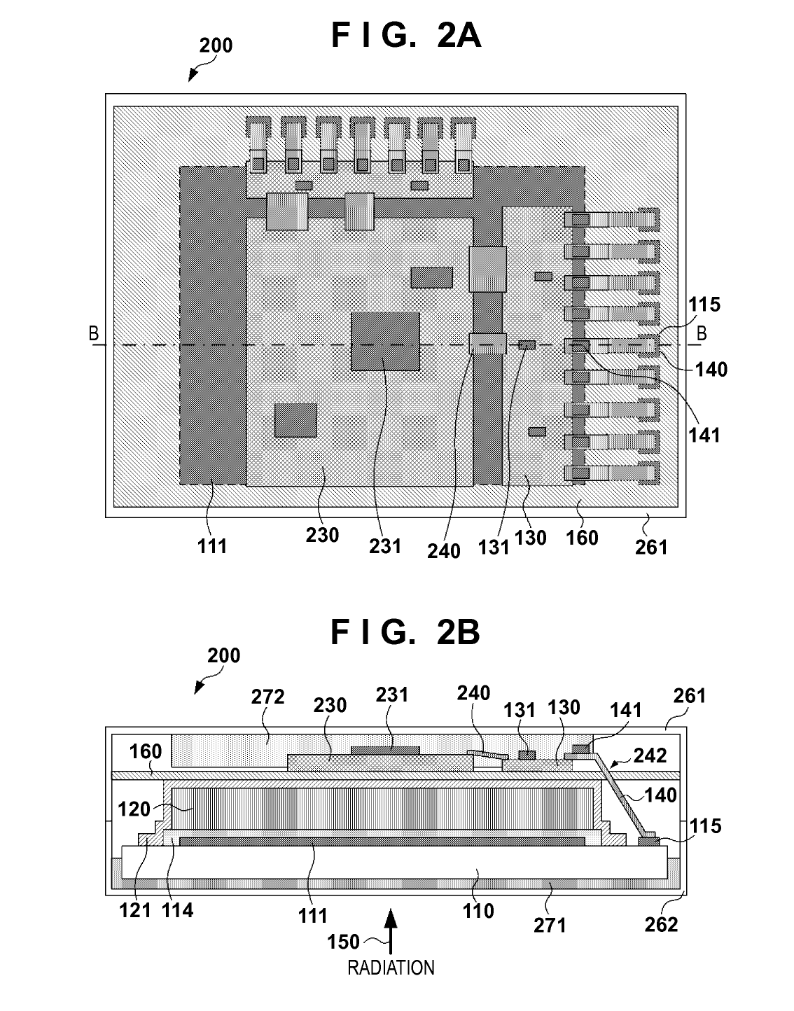

An example of a structure of a radiation detection apparatus 200 according to a second embodiment of the present invention will now be described with reference to FIGS. 2A and 2B. FIG. 2A is a plan view of the radiation detection apparatus 200, and FIG. 2B is a cross-sectional view taken along the line B-B in FIG. 2A. The radiation detection apparatus 200 can mainly include a sensor unit and a cover for accommodating and protecting the sensor unit. Since the sensor unit of the radiation detection apparatus 200 has the similar configuration as that of the sensor unit 100 illustrated in FIGS. 1A and 1B, the same reference numerals are given to components that are same as those described with reference to FIGS. 1A and 1B, and any duplicated descriptions thereof are omitted. In FIG. 2A, for illustrative purposes, the upper surface of the cover is omitted. The pixel array 111, part of the connection portion 140, and the connection terminal 115, which are shown in FIG. 2A, cannot actually be viewed since the electromagnetic shield layer 160 exists.

The cover can be constituted by an upper cover 261 and a lower cover 262. The lower cover 262 is located on the side that the radiation 150 enters, and may be made from a material, such as amorphous carbon and a resin, that absorbs little amount of radiation. The radiation detection apparatus 200 can have, in addition to the circuit board 130, a circuit board 230. Circuits that include ICs 231 or the like are formed on the circuit board 230. The circuit board 230 may have the same configuration as that of the circuit board 130, and any duplicated description thereof is omitted. A circuit for processing analog signals may be arranged on the circuit board 130, and a circuit for processing digital signals may be arranged on the circuit board 230. In such a case, the circuit board 230 may be arranged closer to the central part than the circuit board 130 is. This is because the radiation detection apparatus 200 then achieves an improvement in resistance to radiation, if the circuit for processing digital signals whose quality is likely influenced by radiation is arranged closer to the central part where radiation is more likely to be absorbed, than the circuit for processing analog signals is. The circuit board 230 and the circuit board 130 are connected to each other via the connection portion 240. The circuit board 130 and the circuit board 230 may be incorporated into a single circuit board. In this case, the circuit board may be sized such that it covers the entire pixel array 111. This allows stress that was applied externally to the circuit board to be distributed over the entire pixel array 111, leading to an improvement in fault-tolerance of the radiation detection apparatus 200.

In contrast to the electromagnetic shield layer 160 of FIGS. 1A and 1B, an electromagnetic shield layer 160 of the radiation detection apparatus 200 according to the present embodiment is larger than the sensor substrate 110 and covers the entire sensor substrate 110. Further, the outer periphery of the electromagnetic shield layer 160 abuts on the upper cover 261. The entire pixel array 111 is thus covered with the electromagnetic shield layer 160, so that the electromagnetic shield effect is further improved. Alternatively, the electromagnetic shield layer 160 may be smaller than the sensor substrate 110 but larger than the pixel array 111. Also in this case, the entire pixel array 111 can be covered with the electromagnetic shield layer 160. The electromagnetic shield layer 160 is provided with openings 242, each of which is, for example, a slit cut at an angle, and the connection portions 140 respectively pass through the openings 242.

The sensor substrate 110 and the lower cover 262 are bonded and fixed to each other with a sensor substrate adhesion layer 271. As the sensor substrate adhesion layer 271, a rubber adhesive material, an acrylic adhesive material, a styrene conjugate diene block copolymer adhesive material, a silicone adhesive material, or the like can be used. In the radiation detection apparatus 200, the radiation-entrance surface 113 of the sensor substrate 110 and the lower cover 262 are adjacent to each other via the sensor substrate adhesion layer 271. In such a configuration, no base for supporting the sensor substrate 110 is necessary, leading to minimization and weight reduction of the radiation detection apparatus 200. According to the present embodiment, the sensor substrate adhesion layer 271 covers not only the radiation-entrance surface 113 but also parts of side surfaces of the sensor substrate 110. This makes it possible to prevent the collision of the sensor substrate 110 against the lower cover 262 due to vibration or the like, and thus the breakage of the sensor substrate 110. It is also possible to arrange the radiation-entrance surface 113 of the sensor substrate 110 so as to be directly adjacent to the lower cover 262, and to arrange the sensor substrate adhesion layer 271 so as to cover only the side surfaces of the sensor substrate 110.

A holding layer 272 is arranged between the circuit boards 130, 230 and the upper cover 261. The holding layer 272 is made from a sponge-like flexible material, such as a foamed rubber and a cellular rubber, and is easily deformed. By allowing the region of the holding layer 272 for holding ICs or the like that are mounted on the circuit boards 130, 230 to be deformed, and making a contact area between the holding layer 272 and the mounted components large, displacement of the mounted components due to vibration or the like of the sensor substrate 110 can be prevented, thereby achieving an improvement in reliability of the connection of the connection portion 140. The radiation detection apparatus 200 of the present embodiment has the same effect as that of the first embodiment.

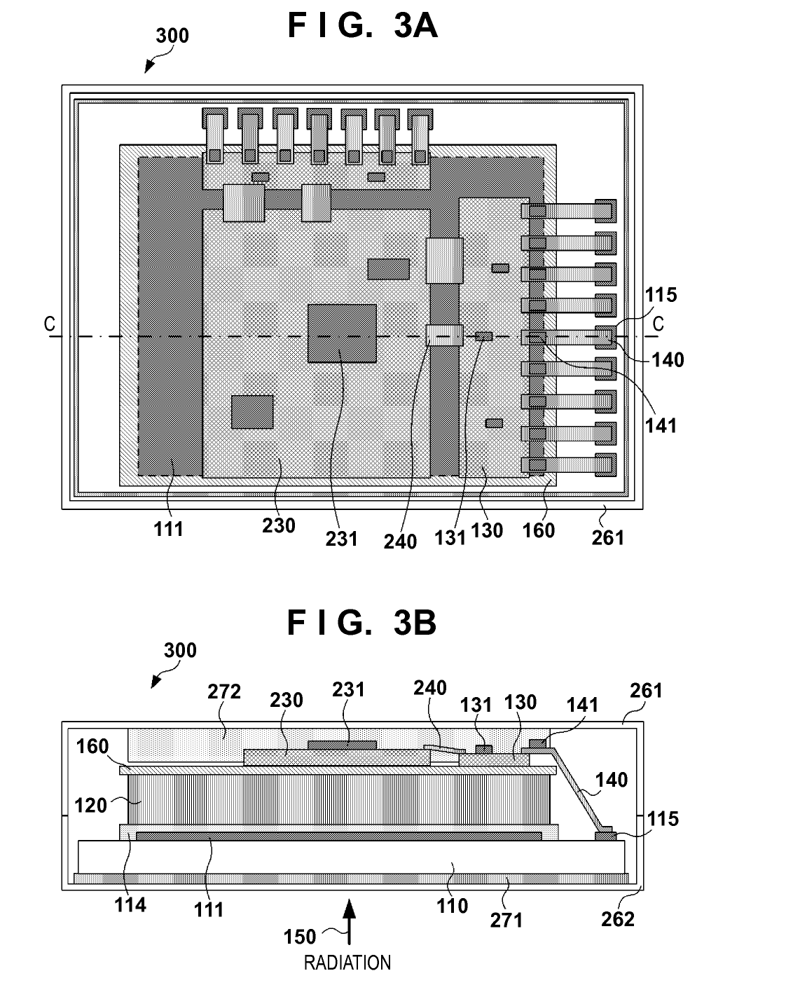

An example of a structure of a radiation detection apparatus 300 according to a third embodiment of the present invention will now be described with reference to FIGS. 3A and 3B. FIG. 3A is a plan view of the radiation detection apparatus 300, and FIG. 3B is a cross-sectional view taken along the line C-C in FIG. 3A. The following will focus on the difference between the radiation detection apparatus 300 and the radiation detection apparatus 200, and any duplicated descriptions therebetween are omitted.

The radiation detection apparatus 300 is a radiation detection apparatus produced by an indirect method, in which a sensor panel and a scintillator panel are separately prepared, and then bonded to each other. The electromagnetic shield layer 160 may also serve as a scintillator substrate on which a scintillator is vapor deposited. With this measure, it is possible to achieve better weight reduction and minimization compared with the case where a scintillator substrate and an electromagnetic shield layer 160 are separately arranged. If an alkali halide material, such as CsI:Na and CsI:Tl, is used as a material of a scintillator, an insulation protection film (not shown) is applied to the surface of the electromagnetic shield layer 160, and then this scintillator material may be vapor deposited thereon.

If the scintillator layer 120 has a column crystal structure of alkali halide such as CsI:Tl, the luminance characteristics are reduced as the amount of radiation absorption increases. In this case, it is possible to restore the luminance characteristics by applying heat that is higher than environmental temperature to the scintillator layer 120. In the radiation detection apparatus 300 according to the present embodiment, the scintillator layer 120 is vapor-deposited on the electromagnetic shield layer 160, and the electromagnetic shield layer 160 is adjacent to the circuit boards 130, 230 directly or via an adhesive material. Therefore, heat that is generated in the circuits, such as the ICs 131, 231, is transferred to the scintillator layer 120 via the circuit boards 130, 230, and the electromagnetic shield layer 160. This makes it possible to restore the luminance characteristics of the scintillator layer 120 and to cool the circuits such as ICs 131, 231. Since the scintillator layer 120 is vapor-deposited on the electromagnetic shield layer 160 and the electromagnetic shield layer 160 is larger than the scintillator layer 120, the heat generated in the circuits is transferred to the entire scintillator layer 120. In order that heat is uniformly transferred to the scintillator layer 120, the IC 231, which is a heat source, may be arranged in the central part of the scintillator layer 120. Alternatively, other circuits such as ICs may be scattered about on the scintillator layer 120. The radiation detection apparatus 300 has the same effect as that of the first embodiment.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-037803, filed Feb. 23, 2012, which is hereby incorporated by reference herein in its entirety.

What is claimed is:

1. A radiation detection apparatus comprising:
a sensor substrate having a first surface and a second surface opposite to the first surface, wherein a pixel array and a connection terminal connected to the pixel array are arranged on the first surface;
a scintillator layer that is arranged on the first surface side of the sensor substrate and converts radiation that entered the second surface side of the sensor substrate into light of a wavelength detectable by the pixel array;
a circuit board that is arranged on a side of the scintillator layer that is opposite to a side facing the sensor substrate, and includes a circuit for controlling an operation of the pixel array; and
a connection portion configured to connect the connection terminal to the circuit board, wherein the scintillator layer is arranged so as to cover the pixel array but expose the connection terminal,
the circuit board and the connection portion are arranged in locations where they do not protrude from the outer edge of the first surface of the sensor substrate.

2. The apparatus according to claim 1, further comprising:
an electromagnetic shield layer configured to shield electromagnetic waves that are generated by the circuit included in the circuit board,
wherein the electromagnetic shield layer is arranged between the circuit board and the scintillator layer.

3. The apparatus according to claim 2,
wherein the electromagnetic shield layer is larger than the pixel array.

4. The apparatus according to claim 2,
wherein the electromagnetic shield layer is larger than the first surface of the sensor substrate, and has an opening through which the connection portion passes.

5. The apparatus according to claim 3,
wherein the scintillator layer is vapor-deposited on the electromagnetic shield layer.

6. The apparatus according to claim 5,
wherein the circuit board is adjacent to the electromagnetic shield layer directly or via an adhesion layer, so that heat generated in the circuit included in the circuit board is transferred to the scintillator layer.

7. The apparatus according to claim 1, further comprising:
a cover configured to accommodate the sensor substrate, the scintillator layer, the circuit board, and the connection portion,
the second surface of the sensor substrate being adjacent to the cover directly or via an adhesion layer.
